(19) United States
(12) Patent Application Publication
(10) Pub. No.: US 2025/0314508 A1
(43) Pub. Date: Oct. 9, 2025

(54) ELECTROMAGNETIC FLOWMETER

(71) Applicant: Azbil Corporation, Tokyo (JP)

(72) Inventor: Kentaro KITAHORI, Tokyo (JP)

(73) Assignee: Azbil Corporation, Tokyo (JP)

(21) Appl. No.: 19/171,347

(22) Filed: Apr. 6, 2025

(30) Foreign Application Priority Data
Apr. 8, 2024 (JP) 2024-062198

(51) Int. Cl. G01F 1/60; G01F 15/06

(52) U.S. Cl. CPC G01F 1/60; G01F 15/06

(57) ABSTRACT

The disclosure makes it possible to uniformly and easily perform on-site diagnostic work for an electromagnetic flowmeter. A storage part 131 stores explanation information about the connection between a measurement circuit 104 and a measurement point for each of multiple measurement points (jumper terminals 105a, 105b, 105c, and 105d) in measurement. An acquisition function part 134 acquires explanation information explaining the connection between the measurement circuit 104 and the measurement point from the storage part 131 for each of multiple measurement points, in response to switching to an inspection mode. A presentation function part 135 presents the explanation information acquired by the acquisition function part 134.

### CROSS-REFERENCE TO RELATED APPLICATION

This application claims the priority benefit of Japanese application serial no. 2024-062198, filed on Apr. 8, 2024. The entirety of the above-mentioned patent application is hereby incorporated by reference herein and made a part of this specification.

### TECHNICAL FIELD

The disclosure relates to an electromagnetic flowmeter.

### BACKGROUND

In flow measurement using an electromagnetic flowmeter, if leakage occurs in the coil current that determines the magnitude of the magnetic field or in the electromotive force generated between the electrodes, the flow measurement cannot be performed accurately. Therefore, for an electromagnetic flowmeter, it is important to perform diagnosis by actually measuring the insulation resistance of paths where leakage may occur, for example, between the coil and ground and between the electrode and ground (Patent Document 1 (Japanese Patent Application Laid-Open No. 2003-106879)).

In insulation resistance inspection that relies on actual measurement as described above, conventionally, an insulation resistance meter is prepared and carried to the site, and then diagnosis is performed by connecting the insulation resistance meter to the equipment to be diagnosed. However, such on-site work requires management and transfer of procedures and know-how, such as how to connect the insulation resistance meter to the equipment, which makes on-site work difficult and prone to variation.

The disclosure makes it possible to uniformly and easily perform on-site diagnostic work for an electromagnetic flowmeter.

### SUMMARY

An electromagnetic flowmeter according to the disclosure includes: an excitation coil applying a magnetic field in a direction perpendicular to a flow direction of a fluid to be measured; an electrode provided at each of locations opposing in a direction perpendicular to the magnetic field applied, and extracting an electromotive force generated in the fluid by the magnetic field applied; a measurement part configured to determine a flow rate based on the electromotive force; a measurement circuit measuring a resistance between the excitation coil and a ground electrode and a resistance between the electrode and the ground electrode; a jumper terminal or a switch for connecting the measurement circuit and a measurement point; and a diagnostic controller. The diagnostic controller includes: a storage part in which explanation information about connection between the measurement circuit and the measurement point is stored for each of a plurality of measurement points based on predetermined inspection content; a reception function part accepting an instruction to switch between a measurement mode and an inspection mode; a switching function part switching between the measurement mode and the inspection mode in response to the reception function part accepting the instruction; an acquisition function part acquiring explanation information explaining connection between the measurement circuit and the measurement point from the storage part for each of the plurality of measurement points in response to switching to the inspection mode; a presentation function part presenting the explanation information acquired by the acquisition function part; and a writing function part writing a measurement result to the storage part in response to resistance measurement being performed by the measurement circuit.

In a configuration example of the above electromagnetic flowmeter, the presentation function part presents the explanation information for each of the plurality of measurement points.

In a configuration example of the above electromagnetic flowmeter, the presentation function part presents an implementation result of the resistance measurement performed by the measurement circuit in addition to the explanation information.

In a configuration example of the above electromagnetic flowmeter, the presentation function part presents the explanation information and the implementation result for each of the plurality of measurement points.

In a configuration example of the above electromagnetic flowmeter, the electromagnetic flowmeter includes a display part disposed on an operation panel on a front surface of a main body. The jumper terminal or the switch is disposed on the operation panel together with the display part, and the presentation function part displays a presentation target on the display part.

As described above, according to the disclosure, a measurement circuit is included to measure the resistance between the excitation coil and the ground electrode and the resistance between the electrode and the ground electrode, and explanation information about the connection between the measurement circuit and the measurement point is presented for each of multiple measurement points in the measurement, so it is possible to uniformly and easily perform on-site diagnostic work for the electromagnetic flowmeter.

### BRIEF DESCRIPTION OF THE DRAWINGS

FIG. 1 is a configuration diagram showing a configuration of the electromagnetic flowmeter according to an embodiment of the disclosure.

FIG. 2 is a configuration diagram showing a partial configuration of the electromagnetic flowmeter according to an embodiment of the disclosure.

FIG. 3 is a configuration diagram showing a partial configuration of another electromagnetic flowmeter according to an embodiment of the disclosure.

FIG. 4 is a configuration diagram showing a hardware configuration of a part of another electromagnetic flowmeter according to an embodiment of the disclosure.

### DESCRIPTION OF THE EMBODIMENTS

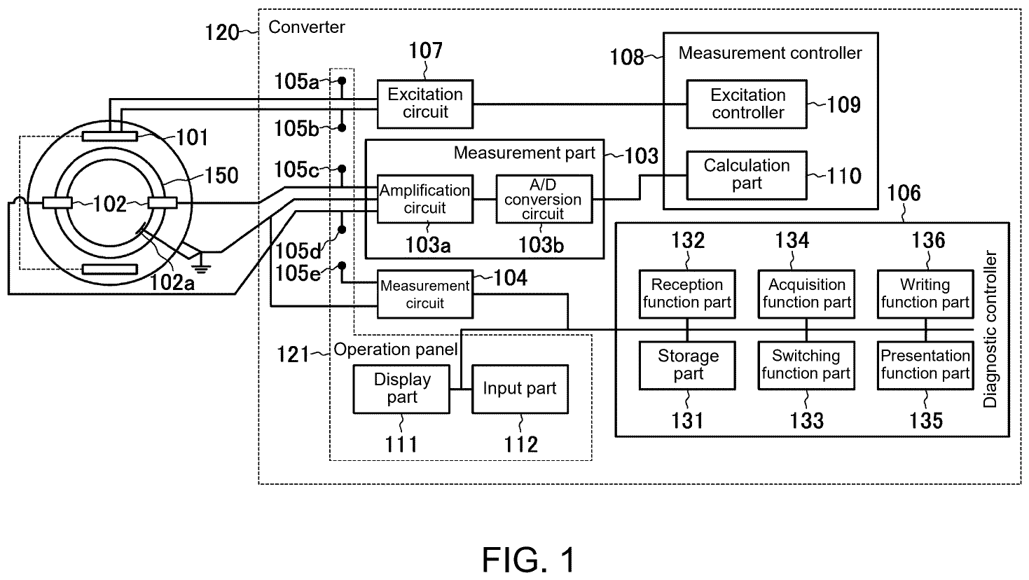

The electromagnetic flowmeter according to an embodiment of the disclosure will be described hereinafter with reference to FIG. 1. This electromagnetic flowmeter includes an excitation coil 101, electrodes 102, a measurement part 103, a measurement circuit 104, jumper terminals 105a, 105b, 105c, 105d, and 105e, a diagnostic controller 106, a display part 111, and an input part 112. In addition, this electromagnetic flowmeter includes a measurement controller 108. The measurement part 103, the measurement circuit 104, the diagnostic controller 106, and the measurement controller 108 are accommodated in a converter 120.

The excitation coil 101 applies a magnetic field in a direction perpendicular to a flow direction of a fluid flowing through a measurement tube 150. The magnetic field is generated by applying a rectangular wave current of a set frequency from an excitation circuit 107 to the excitation coil 101 under the control of the excitation circuit 107 of the measurement controller 108.

The electrodes 102 are provided at locations opposing in a direction perpendicular to the magnetic field applied from the excitation coil 101, and extracts an electromotive force generated in the fluid by the applied magnetic field. The measurement part 103 outputs the extracted electromotive force to a calculation part 110 of the measurement controller 108. For example, an electromotive force based on a potential of a ground electrode 102a, which is arranged in contact with the fluid flowing through the measurement tube 150, is output. The measurement part 103 includes, for example, an amplification circuit 103a and an A/D conversion circuit 103b. The extracted electromotive force is amplified by the amplification circuit 103a and converted into a digital signal by the A/D conversion circuit 103b. Based on the converted digital signal, the calculation part 110 calculates a flow rate value.

The measurement circuit 104 measures the resistance between the excitation coil 101 and the ground electrode 102a, and the resistance between the electrode 102 and the ground electrode 102a. The jumper terminals 105a, 105b, 105c, 105d, and 105e are terminals for an operator to connect the measurement circuit 104 and a measurement point on-site during offline. During online, the jumper terminals 105a, 105b, 105c, 105d, and 105e are disconnected from the measurement part 103. The measurement circuit 104 measures the resistance between the ground and a measurement target connected to the jumper terminal 105e.

For example, by connecting the jumper terminal 105a and the jumper terminal 105e, the measurement circuit 104 is capable of measuring the resistance between one terminal of the excitation coil 101 and the ground. Further, by connecting the jumper terminal 105b and the jumper terminal 105e, the measurement circuit 104 is capable of measuring the resistance between the other terminal of the excitation coil 101 and the ground.

In addition, by connecting the jumper terminal 105c and the jumper terminal 105e, the measurement circuit 104 is capable of measuring the resistance between one electrode 102 and the ground. Further, by connecting the jumper terminal 105d and the jumper terminal 105e, the measurement circuit 104 is capable of measuring the resistance between the other electrode 102 and the ground. It is also possible to respectively provide jumper terminals for measuring the ground resistance of a shield wire used for noise countermeasure in a connection line of the electrode 102. By using these jumper terminals, it is possible to measure the ground resistance of the shield wire of one electrode 102 and the ground resistance of the shield wire of the other electrode 102.

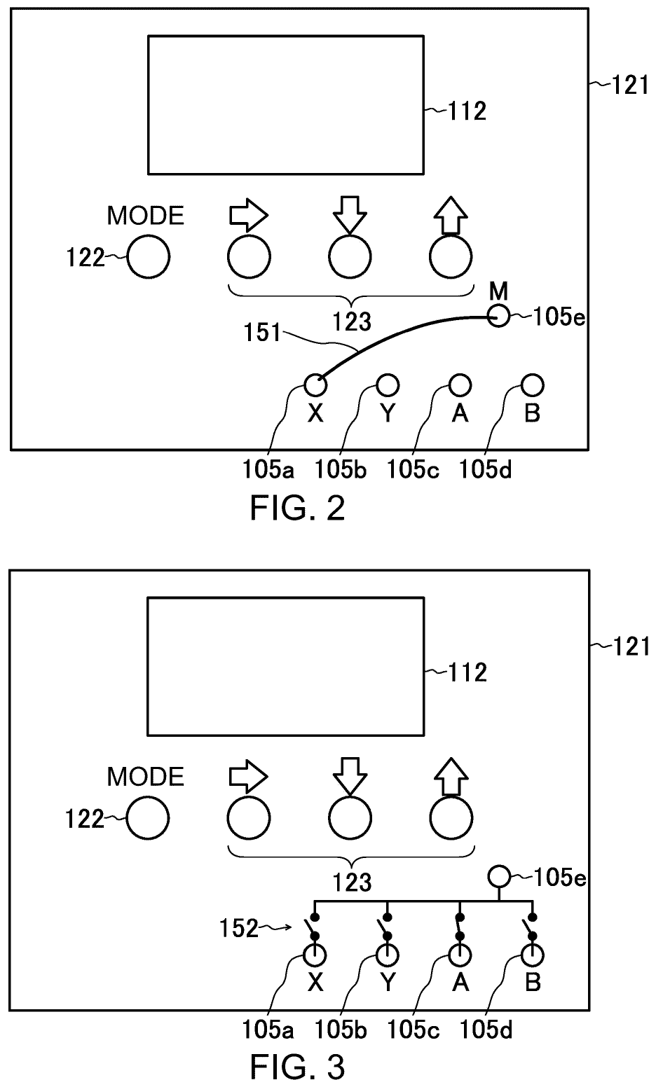

For example, as shown in FIG. 2, this electromagnetic flowmeter includes a display part 111 disposed on an operation panel 121 on a front surface of the converter 120 (main body), and the jumper terminals 105a, 105b, 105c, 105d, and 105e are disposed on the operation panel 121 together with the display part 111.

For example, an identification symbol “X” is engraved near the jumper terminal 105a for connection with the excitation coil 101, an identification symbol “Y” is engraved near the jumper terminal 105b for connection with the excitation coil 101, an identification symbol “A” is engraved near the jumper terminal 105c for connection with the electrode 102, and an identification symbol “B” is engraved near the jumper terminal 105d for connection with the electrode 102. Besides, an identification symbol “M” is engraved near the jumper terminal 105e of the measurement circuit 104. In addition, on the operation panel 121, a mode switching button 122, a cursor button 123, etc. can be provided as the input part 112. By making the display part 111 a touch panel, it is also possible to use the display part 111 as the input part 112.

The diagnostic controller 106 includes a storage part 131, a reception function part 132, a switching function part 133, an acquisition function part 134, a presentation function part 135, and a writing function part 136.

The storage part 131 stores explanation information about the connection between the measurement circuit 104 and the measurement point for each of multiple measurement points (jumper terminals 105a, 105b, 105c, and 105d) based on predetermined inspection content. For example, explanation information such as “Test1: Connect terminal M with terminal X”, “Test2: Connect terminal M with terminal Y”, “Test3: Connect terminal M with terminal A”, and “Test4: Connect terminal M with terminal B” is stored in the storage part 131.

The reception function part 132 accepts an instruction to switch between a measurement mode and an inspection mode. For example, a switching instruction input by the operator through an operation of the input part 112 is accepted by the reception function part 132. The switching function part 133 switches between the measurement mode and the inspection mode in response to the reception function part 132 accepting the instruction.

In response to switching to the inspection mode, the acquisition function part 134 acquires explanation information explaining the connection between the measurement circuit 104 and the measurement point from the storage part 131 for each of multiple measurement points. The presentation function part 135 presents the explanation information acquired by the acquisition function part 134. The writing function part 136 writes a measurement result to the storage part 131 in response to resistance measurement being performed by the measurement circuit 104. The measurement result written to the storage part 131 can be read out by a higher-level device in a control system connected with the electromagnetic flowmeter by communication using fieldbus or the like, and can be shared throughout the entire system.

Additionally, the presentation function part 135 is capable of presenting an implementation result of resistance measurement performed by the measurement circuit 104 along with the explanation information. The presentation function part 135 presents the explanation information and the implementation result for each of multiple measurement points. The presentation function part 135 displays a presentation target on the display part 111.

For example, in response to the reception function part 132 accepting the switching instruction through the operation input of the operator on the mode switching button 122, thereby switching to the inspection mode, the acquisition function part 134 extracts “Test1: Connect terminal M with terminal X” from the storage part 131. Subsequently, the presentation function part 135 displays and outputs the extracted “Test1: Connect terminal M with terminal X” on the display part 111. By visually confirming this display, the operator connects the jumper terminal 105a and the jumper terminal 105e with a jumper wire 151, and performs resistance measurement on one wiring of the excitation coil 101. In response to this measurement being performed, the writing function part 136 writes the measurement result to the storage part 131. Further, the presentation function part 135 displays the measurement result on the display part 111.

In response to the presentation function part 135 presenting the result of measurement using the jumper terminal 105a, the acquisition function part 134 extracts the explanation for the next measurement point, “Test2: Connect terminal M with terminal Y,” from the storage part 131. The presentation function part 135 displays and outputs the extracted “Test2: Connect terminal M with terminal Y” on the display part 111. By visually confirming this display, the operator connects the jumper terminal 105b and the jumper terminal 105e with the jumper wire 151, and performs resistance measurement on the other wiring of the excitation coil 101. For example, after connecting the terminals with the jumper wire 151, the measurement of Test2 is performed through the operation input of the operator on the cursor button 123. In response to this measurement being performed, the writing function part 136 writes the measurement result to the storage part 131. Further, the presentation function part 135 displays the measurement result on the display part 111.

In response to the presentation function part 135 presenting the result of measurement using the jumper terminal 105b, the acquisition function part 134 extracts the explanation for the next measurement point, “Test3: Connect terminal M with terminal A,” from the storage part 131. The presentation function part 135 displays and outputs the extracted “Test3: Connect terminal M with terminal A” on the display part 111. By visually confirming this display, the operator connects the jumper terminal 105c and the jumper terminal 105e with the jumper wire 151, and performs resistance measurement on the wiring of one electrode 102. In response to this measurement being performed, the writing function part 136 writes the measurement result to the storage part 131. Further, the presentation function part 135 displays the measurement result on the display part 111.

In response to the presentation function part 135 presenting the result of measurement using the jumper terminal 105c, the acquisition function part 134 extracts the explanation for the next measurement point, “Test4: Connect terminal M with terminal B,” from the storage part 131. The presentation function part 135 displays and outputs the extracted “Test4: Connect terminal M with terminal B” on the display part 111. By visually confirming this display, the operator connects the jumper terminal 105d and the jumper terminal 105e with the jumper wire 151, and performs resistance measurement on the wiring of the other electrode 102. In response to this measurement being performed, the writing function part 136 writes the measurement result to the storage part 131. Further, the presentation function part 135 displays the measurement result on the display part 111.

It should be noted that, in the above description, when a measurement result is displayed, the display for the next measurement is presented automatically, but the disclosure is not limited thereto. For example, an instruction reception button can be provided to accept an instruction for transitioning to the next measurement along with the display of the measurement result. By operating the button that accepts the transitioning instruction, it is possible to display the explanation for the next measurement. Additionally, in the inspection mode, it is possible to display an indication that the system is in the inspection mode on the display part 111 along with the display of explanation.

Furthermore, the presentation function part 135 is capable of displaying a mode switching button for switching between the measurement mode and the inspection mode on the display part 111 with a touch panel, along with the display of explanation. By operating the button that accepts the mode switching instruction, the measurement is performed. It is also possible to display the instruction reception button described above on the display part 111 with a touch panel.

In addition, while the above description realizes the connection between any of the jumper terminals 105a, 105b, 105c, and 105d and the jumper terminal 105e and the switching of connection using the jumper wire 151, as shown in FIG. 3, these connections and the switching of connection can be performed using a switch 152.

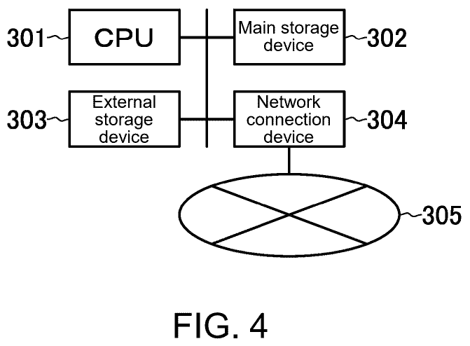

It should be noted that the diagnostic controller 106 described above can be configured as computer equipment including a CPU (Central Processing Unit) 301, a main storage device 302, an external storage device 303, a network connection device 304, etc., as shown in FIG. 4, and the functions of the storage part 131, the reception function part 132, the switching function part 133, the acquisition function part 134, the presentation function part 135, and the writing function part 136 described above can be realized by the CPU 301 operating (executing a program) according to a program expanded in the main storage device 302. The network connection device 304 connects to a network 305. Furthermore, it is possible to distribute the functions across multiple pieces of computer equipment.

As described above, according to the disclosure, a measurement circuit is included to measure the resistance between the excitation coil and the ground electrode and the resistance between the electrode and the ground electrode, and explanation information about the connection between the measurement circuit and the measurement point is presented for each of multiple measurement points based on predetermined inspection content, so it is possible to uniformly and easily perform on-site diagnostic work for the electromagnetic flowmeter.

It should be noted that the disclosure is not limited to the embodiments illustrated above, and it is clear that many variations and combinations can be implemented by those with ordinary knowledge in this field within the technical concept of the disclosure.

What is claimed is:

1. An electromagnetic flowmeter, comprising:
an excitation coil applying a magnetic field in a direction perpendicular to a flow direction of a fluid to be measured;
an electrode provided at each of locations opposing in a direction perpendicular to the magnetic field applied, and extracting an electromotive force generated in the fluid by the magnetic field applied;
a measurement part configured to determine a flow rate based on the electromotive force;
a measurement circuit measuring a resistance between the excitation coil and a ground electrode and a resistance between the electrode and the ground electrode;
a jumper terminal or a switch for connecting the measurement circuit and a measurement point; and
a diagnostic controller,
wherein the diagnostic controller comprises:
a storage part in which explanation information about connection between the measurement circuit and the measurement point is stored for each of a plurality of measurement points based on predetermined inspection content;
a reception function part accepting an instruction to switch between a measurement mode and an inspection mode;
a switching function part switching between the measurement mode and the inspection mode in response to the reception function part accepting the instruction;
an acquisition function part acquiring explanation information explaining connection between the measurement circuit and the measurement point from the storage part for each of the plurality of measurement points in response to switching to the inspection mode;
a presentation function part presenting the explanation information acquired by the acquisition function part; and
a writing function part writing a measurement result to the storage part in response to resistance measurement being performed by the measurement circuit.

2. The electromagnetic flowmeter according to claim 1, wherein the presentation function part presents the explanation information for each of the plurality of measurement points.

3. The electromagnetic flowmeter according to claim 1, wherein the presentation function part presents an implementation result of the resistance measurement performed by the measurement circuit in addition to the explanation information.

4. The electromagnetic flowmeter according to claim 3, wherein the presentation function part presents the explanation information and the implementation result for each of the plurality of measurement points.

5. The electromagnetic flowmeter according to claim 1, comprising a display part disposed on an operation panel on a front surface of a main body,
wherein the jumper terminal or the switch is disposed on the operation panel together with the display part, and
the presentation function part displays a presentation target on the display part.
